(19) United States
(12) Patent Application Publication
(10) Pub. No.: US 2018/0317326 A1
(43) Pub. Date: Nov. 1, 2018

(54) METHOD AND APPARATUS FOR BONDING FLEXIBLE WIRES

(71) Applicants: DENSO WAVE INCORPORATED, Chita-gun (JP); DENSO CORPORATION, Kariya-city (JP)

(72) Inventors: Takeshi NAGANUMA, Chita-gun (JP); Hideaki KANIE, Chita-gun (JP); Akinari HIGASHIDA, Chita-gun (JP); Koji KONDO, Kariya-city (JP)

(73) Assignees: DENSO WAVE INCORPORATED, Chita-gun (JP); DENSO CORPORATION, Kariya-city (JP)

(21) Appl. No.: 15/938,256

(22) Filed: Mar. 28, 2018

(30) Foreign Application Priority Data
Apr. 28, 2017 (JP) 2017-090306

(51) Int. Cl. H05K 3/36; H05K 3/34; B23K 3/04; H05K 1/02

(52) U.S. Cl. CPC H05K 3/363; H05K 3/3494; H05K 2203/0195; H05K 1/02; B23K 3/04

(57) ABSTRACT

An apparatus for bonding flexible printed wires to non-flexible printed wires is provided. The apparatus incudes a heater; and a heating tool heated by the heater and formed to have a heating chip. The heating chip has a height direction and a heating surface directed in the height direction. The heating surface is moved toward the flexible wires to press the flexible wires formed on the non-flexible printed wires. A solder portion is mounted on, at least, ones of the flexible printed wires and the non-flexible printed wires, the heating tool melting the solder portion for a mutual connection between the flexible and non-flexible printed wires when the heating surface of the heating tool is pressed onto the flexible printed wires. The pressing surface is formed as a curved surface having a central part which protrudes outward more than other parts thereof.

### CROSS-REFERENCE TO RELATED APPLICATION

This application is based on and claims the benefit of priorities from earlier Japanese Patent Application No. 2017-90306 filed Apr. 28, 2017, the description of which is incorporated herein by reference.

### BACKGROUND

### Technical Field

The present invention relates to an apparatus and method for bonding printed wires of electrical circuits, and, in particular, to an apparatus and method for electrically bonding printed wires of electrical circuits, one of which is a flexible printed circuit board, to other printed wires.

### Related Art

There is known a thermal compressing bonding method used to bond the printed wires of an FPC (Flexible Printed Circuit) board and the printed wires of a PCB (Printed-Circuit Board). In this bonding, one of such bonding ways is disclosed by JP H11-195870 A. This known publication directed to a bonding apparatus which uses solder as a bonding medium. Practically, terminals of a circuit board have solder portions, and terminals of an FPC board which are overlapped on the solder portions. A heating tool whose temperature is controlled at a predetermined value is applied to the rear surface of the FPC board with a predetermined pressure thereon, so that the circuit board terminals and the FPC terminals are thermocompression bonded to each other.

However, in the apparatus disclosed by the forgoing known publication, the heating tool has a lower surface formed to act as a pressing surface so that the lower surface is applied to an FPC board. In addition, the lower surface is formed to be flat. Due to this flat pressing surface, when the heating tool is tilted or unevenly worn, or the circuit board is warped, the pressing surface of the heating tool has portions pressing the FPC board at pressure values higher than other portions of the pressing surface. Such higher-pressure applying portions are positionally shifted from a central portion of the pressing surface, resulting in the solder portion causing an uneven spread of melted solder.

This uneven spread of melded solder is true of flexible printed wires of an FFT (Flexible Flat Cable), and not limited to only flexible printed wires of the FPC.

### SUMMARY

It is thus desired to reduce the melted solder paste from spreading unevenly during a soldering step of various flexible printed wires.

In view of the foregoing situation, a first mode of the present disclosure provides an apparatus for bonding flexible printed wires to non-flexible printed wires, comprising: a heater; and a heating tool heated by the heater and formed to have a heating chip, the heating chip having a height direction and a heating surface directed in the height direction, the heating surface being moved toward the flexible wires to press the flexible wires formed on the non-flexible printed wires, a solder portion being mounted on, at least, ones of the flexible printed wires and the non-flexible printed wires, the heating tool melting the solder portion for a mutual connection between the flexible and non-flexible printed wires when the heating surface of the heating tool is pressed onto the flexible printed wires, wherein the pressing surface is formed as a curved (arched) surface protruding outward when positionally advancing to a width-directional center of the heating tool in a plane crossing the height direction.

According to the forgoing configuration, the heated heating tool applies pressure to the flexible printed wires, and the solder portion becomes melted. The melted solder portion bonds the flexible printed wires and the non-flexible printed wires with each other.

Using the foregoing first mode of the apparatus, a boding method is provided, the method comprising: preparing, as the flexible printed wires, printed wires formed on an FPC (Flexible Printed Circuit) board, and preparing the solder portion formed on the printed wires formed on the FPC board.

Alternatively, a second mode of the present disclosure provides apparatus for bonding flexible printed wires with non-flexible printed wires to each other, comprising: a heater; and a heating tool heated by the heater and formed to have a heating chip, the heating chip having a height direction and a heating surface directed in the height direction, the heating surface being moved toward the flexible wires to press the flexible wires formed on the non-flexible printed wires, a solder portion being mounted on, at least, ones of the flexible printed wires and the non-flexible printed wires, the heating tool melting the solder portion for mutual connection between the flexible and non-flexible printed wires when the heating surface of the heating tool is pressed onto the flexible printed wires, wherein the pressing surface is formed as a spherical surface protruding outward in the height direction.

This configuration is able to provide functions and advantages which are the same as those described in the foregoing first mode.

### BRIEF DESCRIPTION OF THE DRAWINGS

In the accompanying drawings:

FIG. 1 is an outlined illustration showing a bonding apparatus serving as a flexible-wire bonding apparatus according to an embodiment;

FIG. 2 is an outlined illustration showing a heating tool and printed wires being bonded, according to a prior art;

FIG. 3 is an outlined illustration showing the printed wires bonded by the heating tool according to the prior art;

FIG. 4 is an illustration showing how a crack is caused in a solder portion between the printed wires, according to the prior art;

FIG. 5 is an illustration exemplifying a distribution of pressure provided by the heating tool according to the prior art;

FIG. 6 is a plan view exemplifying a bonded state of the printed wires, according to the prior art;

FIG. 7 is a sectional view showing a heating tool according to a modification of the embodiment;

FIG. 8 is an illustration exemplifying a distribution of pressure provided by the heating tool according to the embodiment;

FIG. 9 is a sectional view showing how bonding is performed between the printed wires;

FIG. 10 is a plan view exemplifying a bonded state of the printed wires, according to the embodiment;

FIG. 11 is a partial sectional view showing how resist is coated; and

FIG. 12 is a partial sectional view illustrating how the coated resist layer stops the solder portion which has been spread.

### DETAILED DESCRIPTION OF THE PREFERRED EMBODIMENTS

With reference to the accompanying drawings, hereinafter will be described various embodiments of a bonding apparatus used for bonding flexible wires.

[Embodiment]

In the present embodiment, the bonding apparatus is provided as a flexible-wire bonding apparatus which is capable of bonding printed wires of a PCB (Printed-Circuit Board) substrate and printed wires of an FPC (Flexible Printed Circuit) board (which is provided as flexible wires) with use of soldering. The printed wires of the PCB substrate and the printed wires of the FPC board thus serve as objects being solder-connected by the flexible-wire bonding apparatus according to the present embodiment.

<Outline of a Bonding Apparatus According to the Present Embodiment>

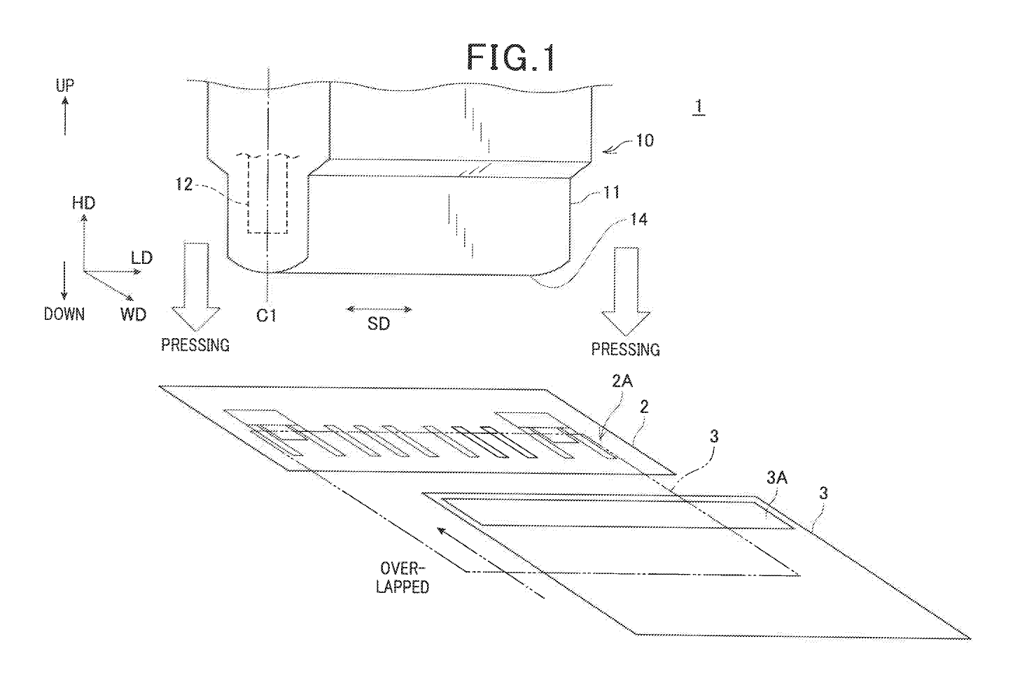

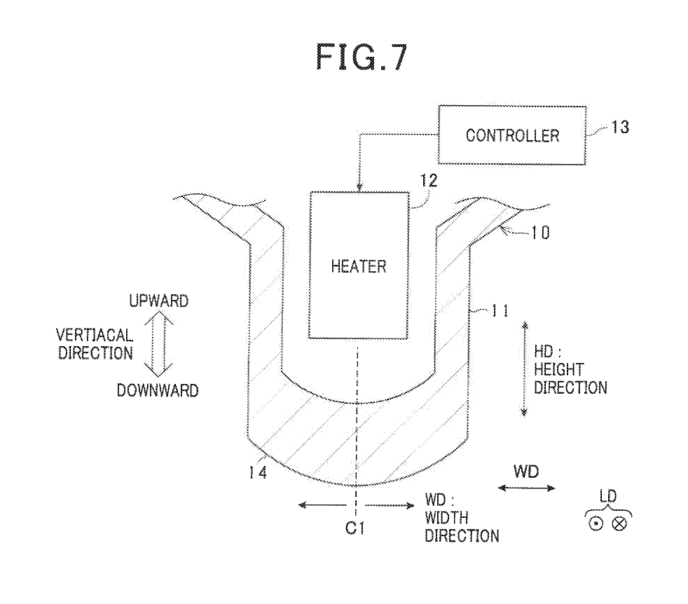

FIG. 1 outlines a bonding apparatus 1 provided with a heating tool 10 and a heater 12 installed in the heating tool 10. The heater 12, which is under control of a controller 13 (refer to FIG. 7), is able to heat the heating tool 10 in a controlled manner. By way of example, the heating tool 10 is attached, as an end effector, to the end of an arm of an industrial bonding robot (not shown) working in a factory. During a bonding step, objects being bonded with each other are prepared and placed under the bonding apparatus 1 by using an industrial delivery robot (not shown), for instance.

In the present embodiment, such objects are prepared as an FPC board 2 and a PCB substrate 3, and printed wires (i.e., terminal portions of flexible wires) 2A of the FPC board 2 are placed on designated printed wires 3A of the PCB substrate 3 by the industrial delivery robot. The bonding robot is then driven to move its arm downward toward the printed wires 3A of the PCB substrate 3. On the front surface of the printed wires 2A of the FPC board 2, a solder portion 53 is previously mounted. A pressing mechanism (not shown) mounted in the arm of the bonding robot is thus able to press the heating tool 10 onto the printed wires 2A of the terminal portion of the FPC board 2, so that the solder portion 53 is subjected to heating and pressurization between the between the printed wires 2A (terminal portions) of the FPC board 2 and the designated printed wires 3A of the PCB substrate 3. This heating and pressing steps make it possible to melt the solder portion 53 to be melted therebetween for bonding both printed wires 2A and 3A.

Before describing features of a bonding structure of the bonding apparatus 1, a conventional bonding apparatus will be described for an easier and comparative understanding such features.

<Description of Conventional Bonding Apparatus>

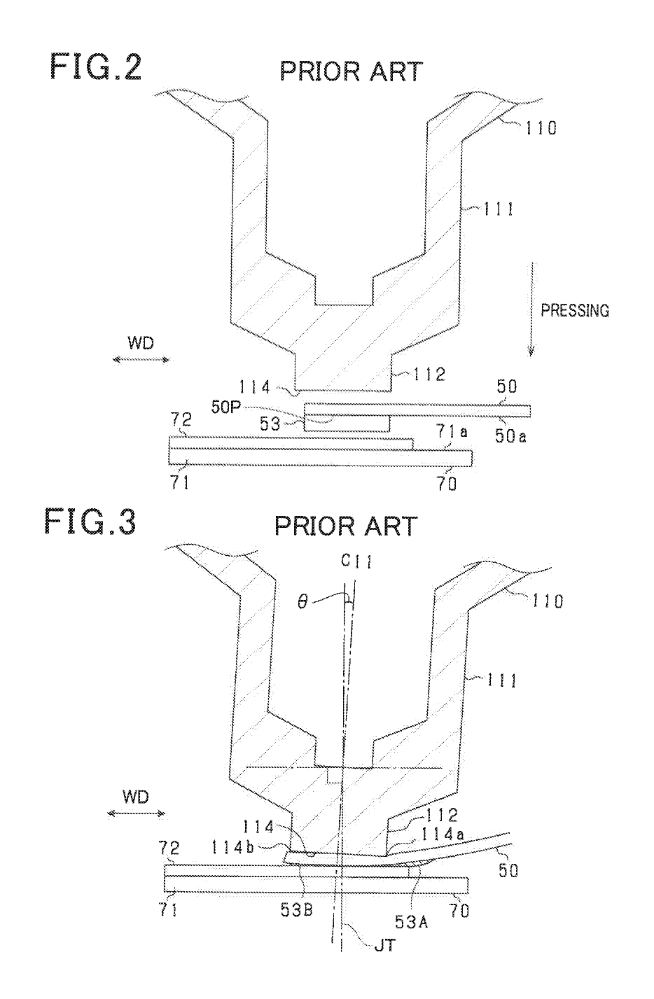

First, with reference of FIG. 2 to FIG. 6, a conventional flexible-wire bonding apparatus will now be described for easier understanding of the flexible-wire bonding apparatus according to the present embodiment.

As shown in FIG. 2, a known flexible-wire bonding apparatus is provided with a heating tool 110. This heating tool 110 includes a heater (not shown) which is mounted therein and a rectangular heating chip 111 in a section taken along a width direction WD. The temperature of the heating chip 111 is controlled at predetermined values by driving the heater in a controlled manner. The heating chip 111 has a protruded tip portion 112. The tip portion 112 has an end surface which serves as a pressing surface 114, which applies pressure to an FPC board 50 when the heating tool 110 is pressed downward. The pressing surface 114 is formed as a flat and rectangular surface when being viewed upward from the lower side of the heating chip 111.

The heating tool 110 is configured to be moved downward, i.e., toward the FPC board 50, by a not-shown pressing mechanism. The pressing mechanism is provided with driving members including an air cylinder which is able to move the heating tool 110 downward at a specified force for a specified period of time. The pressing mechanism is able to set arbitrarily a force and a time for the pressurization when the heating tool 110 is moved downward.

The board 50 has printed wires (not shown) serving as electrical circuits. The printed wires are made of copper and provided on a frontal surface 50a (a lower surface) of the FPC board 50. The printed wires have a predetermined section on which a solder portion 53 having a predetermined thickness is arranged previously. The printed wires and the solder portion 53 are electrically connected to each other. The solder portion 53 has a width and the tip portion 112 of the heating chip 111 has a width, where both of the widths are set to be substantially equal to each other.

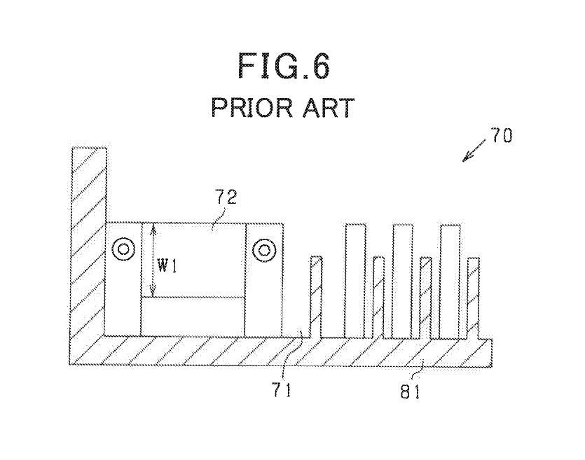

As the PCB substrate, as shown in FIG. 6, there is provided a PCB substrate 70 which has a plate portion 71 and wired lines 72. The plate portion 71 is made of electrically insulated material and formed into a plate shape. The wired lines 72, which serve as non-flexible wires, are made of copper and formed on a front surface (the upper surface) 71a of the plate portion 71.

Printed wires 72 on the PCB substrate 70 and printed wires on the FPC board 50 are connected to each other using soldering in order to manufacturing electric circuits. In this manufacturing, the PCB substrate 70 and the FPC board 50 are positioned such that the printed wires 72 are opposed to the solder portion 53. Then the tip portion 112 of the heating tool 110 is set to a predetermined temperature. The heating tool 110 is moved downward at a designated force for a designated period of time, resulting in that the pressing surface 114 presses the FPC board 50. Pressing the heated heating tool 110 makes it possible to melt the solder portion 53 due to the temperature, thereby bonding the printed wires 72 on the PCB substrate 70 and the printed wires 50P on the FPC board 50 with each other, with the melted solder portion 53 holding the printed wires 72 and 50P. On completion of this connection, the heating tool 110 is moved upward, that is, taken away from the FPC board 50.

During this pressing operation of the heating tool 110, as shown in FIG. 3, there are some cases in which the heating tool 110 is moved for pressing in a state where a center line C11 virtually drawn on the heating tool 110 has a tilt against the vertical direction JT (refer to an angle θ in FIG. 3). If this tilt happens, the pressing surface of the tip portion 112 tilts relative to the horizontal surface, that is, to both of the PCB substrate 70 and the FPC board 50.

This tilt will cause there to be uneven portions on the pressing surface 114, whose distances from the printed wires 72 (of the PCB substrate 70) are different from each other, such as a larger-distance portion 114a and a smaller-distance portion 114b if such portions are categorized into two portions. In this case, the pressure applied to the FPC board 50 at the larger-distance portion 114a of the pressure surface 114 becomes higher, while, in contrast, the pressure applied to the FPC board 50 at the smaller-distance portion 114b of the pressure surface 114 becomes lower.

This imbalance of the distances due to the tilted pressing geometry will cause changes in the temperature increasing speed in the solder portion 53. Specifically, a section in the solder portion 53, which is pressed by the lager-distance portion 114a, increases the temperature more quickly than the other portion, thus allowing such a soldering section to be melted at the beginning. If this imbalanced melt occurs in the solder portion 53, the first soldered section physically pulls over a later soldered section during their melting procedure. In the case shown in FIG. 3, in the solder portion 53, a melted section 53B melted by pressing of the smaller-distance portion 114b is pulled by a melted section 53A melted by pressing of the larger-distance portion 114a.

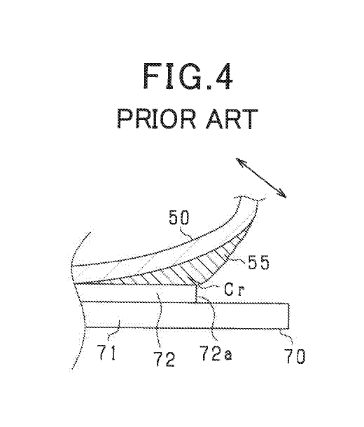

FIG. 4 pictorially shows a crack Cr which has occurred in a solder portion 55 at an edge 72a of the printed wires 72 of the PCB substrate 70 shown in FIG. 3.

In a case where a melded solder portion 53A (shown in FIG. 3) is extended to protrude outwards from the edge 72a of the printed wires 72, the solder portion 55 is shaped discontinuously at the edge 72a of the printed wires 72. When there occurs a distortion due to an application of a force to the FPC board 50 as shown by an arrow in FIG. 4, stress may concentrate on a point of the solder portion 55 which positionally corresponds to the edge 72a of the printed wires 72, which may cause a crack Cr in the solder portion 55.

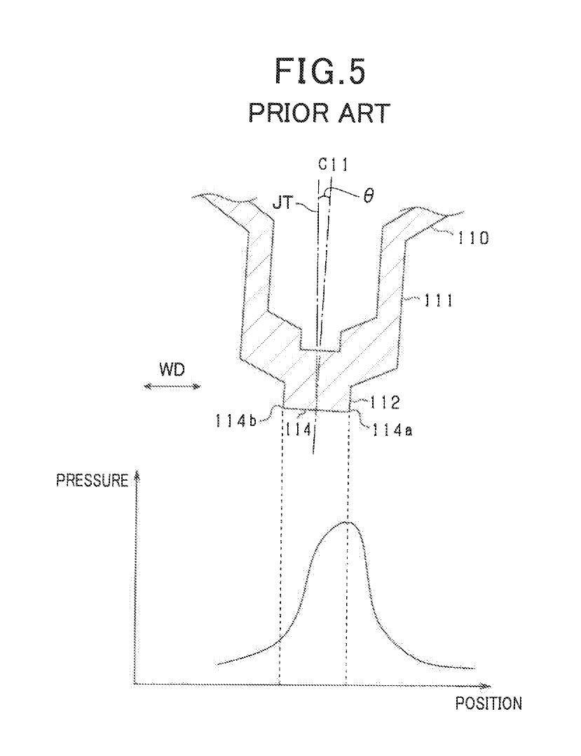

FIG. 5 pictorially shows a relationship between the conventional heating tool 110 which has been tilted during a bonding step and a pressure distribution provided by the conventional heating tool 110. It is clear that, due to the flat pressing surface 114 of the heating tool 110, there occurs a bias in the pressure applied to the printed wires of the FPC board 50. Particularly, a part of the pressing surface 114, which can apply the highest pressure to the printed wires of the FPC board 50, is significantly shifted from the width-directional center line C11 virtually drawn to pass through the heating tool 110.

FIG. 6 shows a plan view of a conventional PCB substrate 70, in which a plate portion 71 is provided and printed wires 72 are formed on the plate portion 71. The printed wires have a width W1, while the plate portion 71 has an outer edge on which a resist 81 is coated. As shown in FIG. 2, the printed wires of the FPC board 50 are bonded to the printed wires 72 of the PCB substrate 70 by using the solder portion 53. The solder portion 53 is made to be opposed to the printed wires 72 in this bonding step. This bonding step produces an electric circuit electrically connecting the PCB substrate 70 and the FPC board 50.

<Detailed Description of Features of the Present Embodiment>

Now, returning to the present embodiment, the bonding apparatus 1 will be detained with reference to FIG. 1 and FIGS. 7-12.

In order to eliminate cracking in the solder portion, the flexible-wire bonding apparatus 1 according to the present embodiment is provided. Steps for a bonding method according to the present embodiment are the same as those described with the foregoing conventional method.

A heating tool 10 is provided with a heating chip 11 and a heater 12. The heater 12 is driven and controlled by a controller 13, so that the temperature of the heating chip 11, that is, the temperature of the heating chip 11, which is applied to objects being solder-connected, can be controlled by the controller 13.

In the present embodiment, the heating tool 10 is provided instead of the foregoing conventional heating tool 110 and the other components are similarly configured to those explained in the foregoing conventional apparatus, so that the components as those explained as above are given the same reference numbers or explained in a simplified manner for the sake of removing redundant explanations.

As shown in FIG. 7, the heating tool 10 is installed, for instance, as an end effector, at the tip of a hand of an industrial robot (not shown). Hence, by controlling actions of the industrial robot, the heating tool 10 can be moved downward and upward in the vertical direction towards objects being connected by the flexible-wire bonding apparatus according to the present embodiment.

In the heating tool 10, the heater 12 is installed within the approximately box-shaped heating chip 11. The temperature of the heating chip 11 is thus controlled at a predetermined value by controlling drive of the heater 12 using the controller 13. The lower surface of the tip portion of the heating chip 11 is configured to act as a pressing surface 14 which presses the FPC board 50. The pressing surface 14 is formed as a curved surface protruding outward, whereby the pressing surface 14 is to be opposed to the FPC board 50 in a bonding step.

The pressing surface 14 in the present embodiment has a rectangular shape when vexing the heating chip 11 in its height direction HD (refer to FIGS. 1 and 7) in which the heating chip 11 is moved up and down in a controlled manner. Furthermore, the pressing surface 14 is formed to be curved and to be symmetric in relation to a virtual central line C1 virtually passing, through the heating chip 11, a center of the heating chip 11 in the width direction WD, when reviewing the heating chip 11 from either of both sides thereof in the longitudinal direction LD (refer to FIGS. 1 and 7). Hence, the pressing surface 14 gradually protrudes outward as positionally advancing to the central part thereof surrounding the central line C1 in the width direction WD.

Alternatively, to the rectangular and curved shape shown above, the pressing surface 14 can be formed to be a spherical surface which gradually protrudes as approaching from an edge to a central part thereof. Depending on shapes of objects being bonded, the shape of the pressing surface, i.e., the heating chip 11 can be chosen.

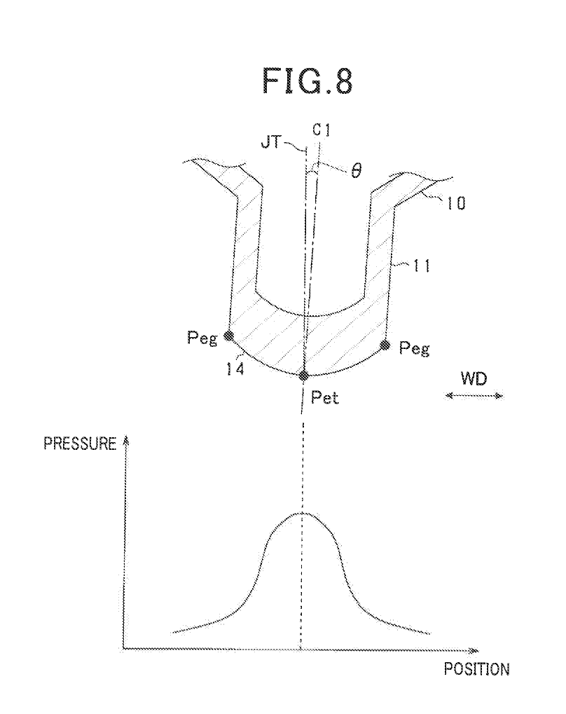

FIG. 8 shows a relationship between the pressing surface 14 of the heating tool 10 according to the present embodiment and a distribution of pressure applied to an object, such as the FPC board 50, when the heating tool 10 is pressed onto the object during a bonding action. As shown, the heating tool 10 is pressed obliquely to the object which is a similar pressing action to that shown in FIG. 3, in which the central line C1 of the heating tool 10 is slightly oblique to the vertical direction. However, since the pressing surface 14 is curved relative to the object, in this case, for the FPC board 50, only a very small positional shift occurs between the center line C1 and a portion of the pressing surface 14 which applies the highest pressure to the FPC board 50. Moreover, the maximum pressure of the pressing surface 14, which is applied to the FPC board 50, is reduced more than that of the conventional pressing surface 114 shown in FIG. 3. In addition, when compared with the pressure curve shown in FIG. 3, change rates in the pressure to the lateral positions shown in FIG. 8 are made smaller thanks to the curved pressing surface 14. This means that, compared with the conventional pressing surface 114, the pressure reduces in a gradual curve from a surface position Pct which presents the maximum pressure when being pressed, as advancing away from the surface position to edges Ped thereof

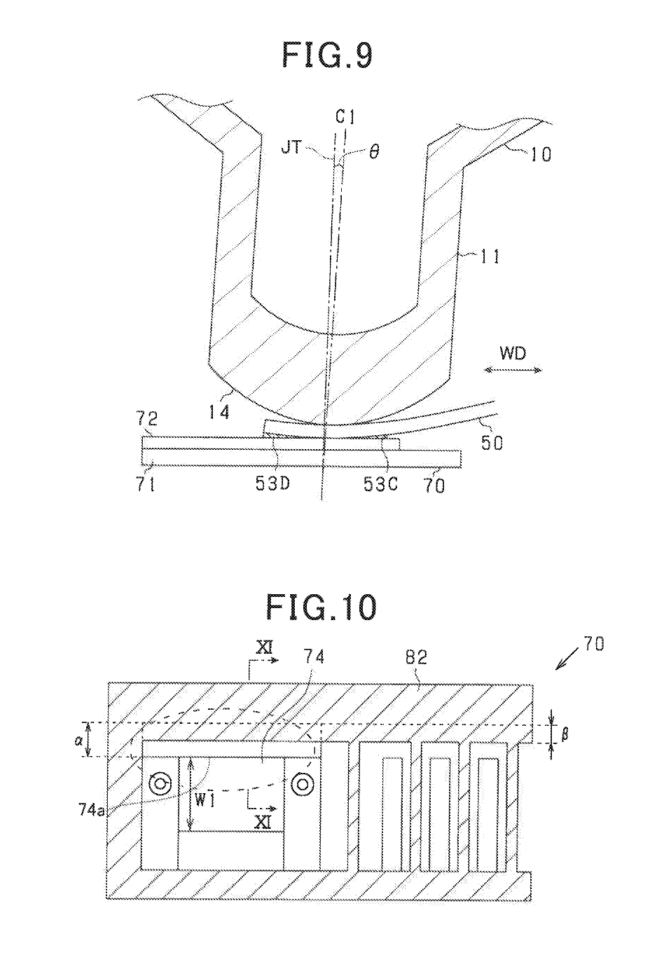

FIG. 9 illustrates a bonding state using the heating tool 10 according to the present embodiment, in which the heating tool 10 is pressed such that the center line C1 thereof is pressed slightly obliquely to the vertical direction JT. In such an oblique pressing action, it is understood that a positional shift made between the printed wires 72 of the PCB substrate 70 and the pressing surface 14 of the heating chip 11 is almost similar to that obtained when the central line C1 is not tilted but being along the vertical line JT of which angle is 90 degrees to the PCB substrate 70. Hence, a portion of the pressing surface 14, which presents the shortest distance to the PCB substrate 70, can be suppressed from being shifted largely from a central part around the central line C1 on the pressing surface 14.

It is therefore possible to suppress a portion of the pressing surface 14, which presents the maximum pressure to the FPC board 50, from being shifted from its central part to another part on the pressing surface 14. As a result, within the solder portion 53, the temperature of a portion pressed by the central part of the pressing surface 14 increases most rapidly so as to be melted at the beginning. When the center line C1 of the heating chip 10 is tilted in the bonding action, the solder portion can be started to be melted from a portion positionally opposed to the central part of the pressing surface 14 in a steady manner. Therefore, as shown in FIG. 10, melted solder portions 53C and 53D spread almost equally in respective directions from the central part around the center line C1 as the bonding process advances. This substantially equal spread of the melted solder portions can be accomplished even if there are uneven wear parts on the pressing surface 14 or there are curves on the printed wires 72 of the PCB substrate 70.

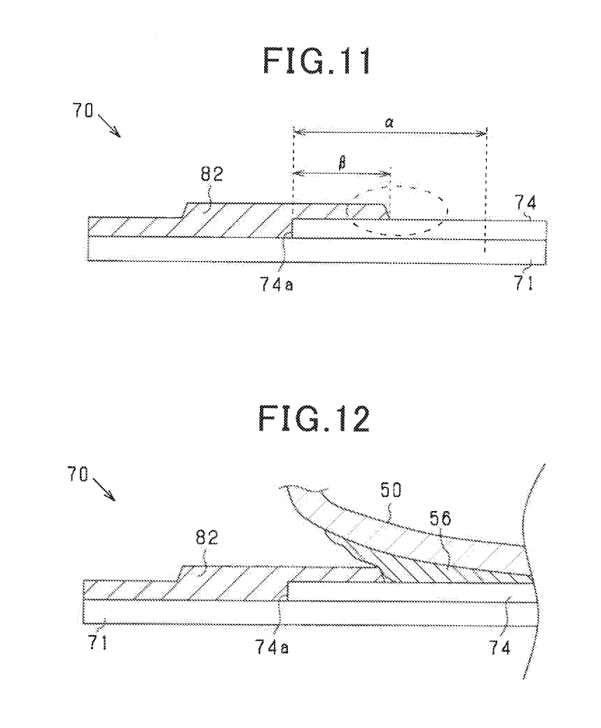

FIG. 10 is a plan view showing the PCB substrate 70 according to the present embodiment, while FIG. 11 is a sectional view taken along a line XI-XI in FIG. 10. As shown, the PCB substrate 70 has a plate portion 71 with an upper surface (i.e., a fontal surface) on which printed wires 74 are formed. The width of the printed wires 74 is set to be larger by a width a more than the width W1 of the conventional printed wires 72 shown in FIG. 10. Because of this extended width, when the solder portion 53 is melted, the melted solder cannot reach an edge 74a of the printed wires 74. That is, the width of the printed wires 74 to be opposed to the solder portion 53 is set to larger than a width to which the melted solder is spread.

In addition, a resist 82 is coated to an outer edge and a predetermined part of the plate portion 71. Practically, the resist 82 is coated on a part of the outer peripheral which is opposed to the solder portion 53 in the printed wires 74 opposed to the solder portion 53. More specifically, as shown in FIG. 11, the resist 82 is coated to cover an area having a width β, which is half the width α of an enlarged area more than the conventional printed wire 72 (shown in FIG. 10) in the printed wires 74. The method for bonding an electric circuit in the present embodiment uses the PCB substrate 70 provided with printed wires 74 and the resist-coated part 82.

FIG. 12 pictorially shows the electric circuit manufactured with use of the PCB substrate 70, in which the resist-coated part 82 and the melted solder portion 56 are located at an end 74a of one of the printed wires 74 of the PCB substrate 70. As shown, the width of the printed wire 74 is set to be larger than the width W1 of the conventional printed wire 72 shown in FIG. 10. Hence, the melted and solidified solder portion 56 has not been spread to reach the end 74a of the printed wire 74. On the printed wire 74, the resist 82 is coated to a part to which the melded solder portion is not spread, so that the end 74a of the printed wire 74 is covered by the resist 82.

For this reason, the melted solder portion is stopped by the coated resist 82 from reaching the end 74a of the printed wires 74. Hence, at the end 74a of the printed wire 74, the solder portion 56 is prevented from being shaped discontinuously, resulting in avoiding concentration of stress in the solder portion 56, thus reducing or avoiding cracks from causing on or in the solder portion 56.

A peel strength was measured, which can be defined as a force necessary for peeling the FPC board 50 which has been soldered according to the bonding techniques of the present embodiment and the conventional one. The test result showed a standard deviation 6 of 0.76 when the present embodiments was adopted, while a standard deviation σ of 1.26 was measured when the conventional bonding technique was adopted.

As described above, the bonding technique of the present embodiment has various advantages.

First, a part of the pressing surface 14, which produces the highest pressure to be applied to the FPC board 50, can be prevented or reduced from being shifted from a central part of the pressing surface 14.

Differently from the conventional flat pressing surface structure, the solder portion always starts to melt from a part opposed to the central part of the pressing surface 14, because the central part of the pressing surface 14 presses the FPC board 50 at a pressure higher than the remaining part. It is thus possible to make the solder portion 53 melt from a portion facing the central part of the pressing surface 14 in a steadier manner, even if the heating tool 10 is tilted in the bonding step, the pressing surface 14 has uneven worn parts, or the printed wire 74 is curved. The central part of the pressing surface 14 is shaped as a rectangular and curved (i.e., arched) surface when the heating tool shown in FIG. 1 is adopted, or as a circular and curved part when the heating tool described before is adopted. Accordingly, according to the present embodiment, when bonding the printed wire of the FPC board 50 to the printed wire 74 of the PCB substrate 70, the melted solder portion is suppressed from spreading unevenly in an area surrounding the solder portion.

Further, the width of the printed wire 74 opposed to the solder portion 53 is larger than the width of an area in which melted solder portion spreads fully. This makes it possible to avoid or reduce the melted solder portion 56 from spreading in an uneven or discontinuous shape. Hence, even when the FPC board 50 deforms due to an application of force, occurrence of cracks can be suppressed in the solder portion 56.

Furthermore, on the surface of the printed wire 74 facing the solder portion 53, the resists 82 is coated on, at least, part of a periphery of an area facing the solder portion 53. The resist 82 is thus coated in the area at which the melted solder cannot arrive on the surface of the printed wire 74, with the result that the coated resist 82 stops the melted solder from reaching the end 74a of the printed wire 74. This stop of the melted solder flow reduces or prevents the solder portion 56 becoming a discontinuous shape at the end 74a of the printed wire 74. This further prevents or reduces cracks from occurring in the solder portion 56.

<Modifications>

Various modifications of the present embodiment can be provided.

In the PCB substrate 70, the resist 82 can be coated in the same way as the conventional resist 81 shown in FIG. 6, if necessary.

The printed wire 74 may be configured to have the same structure shown by the conventional printed wire 72, if necessary.

As described, the pressing surface 14 of the heating chip 11 can be formed into other various shapes, provided that the pressing surface has a curved (or arched) surface which protrudes outwards gradually as approaching a width-directionally or radial central part of the pressing surface. The shape of the pressing surface is not limited to the rectangular and curved shape shown in FIG. 1 or the spherical shape described.

The solder portion 56 can be placed in advance on the printed wires 74 (72) of the PCB substrate 70, in which the solder portion is not always limited to be placed on the printed wires of the FPC board 50 as described. Of course, the solder portion 56 may be placed in advance on both printed wires of the FPC board 50 and the PCB substrate 70.

As an object being bonded according to the foregoing embodiments, printed wires of an FFC (Flexible Flat Cable) can also be adopted, instead of the printed wires of the FPC board 50.

The present invention described above is not limited to the above-described embodiments and various modifications, but can be applied to various other embodiments without departing from the spirit thereof.

What is claimed is:

1. An apparatus for bonding flexible printed wires to non-flexible printed wires, comprising:
a heater; and
a heating tool heated by the heater and formed to have a heating chip, the heating chip having a height direction and a heating surface directed in the height direction, the heating surface being moved toward the flexible wires to press the flexible wires formed on the non-flexible printed wires, a solder portion being mounted on, at least, ones of the flexible printed wires and the non-flexible printed wires, the heating tool melting the solder portion for a mutual connection between the flexible and non-flexible printed wires when the heating surface of the heating tool is pressed onto the flexible printed wires,
wherein the pressing surface is formed as a curved surface protruding outward when positionally advancing to a width-directional center of the heating tool in a plane crossing the height direction.

2. An apparatus for bonding flexible printed wires with non-flexible printed wires to each other, comprising:
a heater; and
a heating tool heated by the heater and formed to have a heating chip, the heating chip having a height direction and a heating surface directed in the height direction, the heating surface being moved toward the flexible wires to press the flexible wires formed on the non-flexible printed wires, a solder portion being mounted on, at least, ones of the flexible printed wires and the non-flexible printed wires, the heating tool melting the solder portion for a mutual connection between the flexible and non-flexible printed wires when the heating surface of the heating tool is pressed onto the flexible printed wires,
wherein the pressing surface is formed as a spherical surface protruding outward in the height direction.

3. A method for manufacturing an electrical circuit by bonding using a flexible-wire bonding apparatus comprising:
a heater; and
a heating tool heated by the heater and formed to have a heating chip, the heating chip having a height direction and a heating surface directed in the height direction, the heating surface being moved toward the flexible wires to press the flexible wires formed on the non-flexible printed wires, a solder portion being mounted on, at least, ones of the flexible printed wires and the non-flexible printed wires, the heating tool melting the solder portion for a mutual connection between the flexible and non-flexible printed wires when the heating surface of the heating tool is pressed onto the flexible printed wires,
wherein the pressing surface is formed as a curved surface protruding outward when positionally advancing to a width-directional center of the heating tool in a plane crossing the height direction,
the method comprising preparing, as the flexible printed wires, printed wires formed on an FPC (Flexible Printed Circuit) board, and
preparing the solder portion formed on the printed wires formed on the FPC board.

4. The method of claim 3, wherein
the non-flexible printed wires which are to be opposed to the solder portion are wider in width than the solder portion which has melted.

5. The method of claim 4, wherein
the non-flexible printed wires which are to be opposed to the solder portion have a surface, the surface including an opposed surface to be opposed to the solder portion and a surrounding surface around the opposed surface, resist being applied to, at least, a part of the surrounding surface.
